(19) United States
(12) Patent Application Publication
(10) Pub. No.: US 2004/0021152 A1
(43) Pub. Date: Feb. 5, 2004

(54) Ga/A1GaN Heterostructure Field Effect Transistor with dielectric recessed gate

(76) Inventors: Chanh Nguyen, Calabasas, CA (US); Jeong-Sun Moon, Chatsworth, CA (US); Wah S. Wong, Montebello, CA (US); Miro Micovic, Newbury Park, CA (US); Paul Hashimoto, Los Angeles, CA (US)

Correspondence Address: TOPE-MCKAY & ASSOCIATES, 23852 PACIFIC COAST HIGHWAY #311, MALIBU, CA, 90265, US

(21) Appl. No.: 10/214,422

(22) Filed: Aug. 5, 2002

(51) Int. Cl. H01L 31/0328

(52) U.S. Cl. 257/192

(57) ABSTRACT

The present invention utilizes the strong piezoelectric effect, found in group-III nitride materials to circumvent the need to selectively remove Gallium Nitride (GaN) in the fabrication of GaN/AlGaN Heterostructure Field Effect Transistors. The transistor is comprised of a semi-insulating substrate 300, a buffer layer 302 which is in continual contact with the semi-insulating substrate 300. A GaN active channel 304 is atop the buffer layer 302. An AlGaN barrier 306 in laid on top of, and is in continual contact with, the GaN active channel 304. Thereafter, there is a source contact 308 and a drain contact 310 both in physical contact with the GaN active channel 308. There is a gate 312 upon the AlGaN barrier 306 and between the source contact 308 and a drain contact 310. At least one dielectric stressor 314 is placed upon the AlGaN barrier 306. The dielectric stressors 314 are between the gate 312 and the source 308 and drain 310 contacts.

### TECHNICAL FIELD

The present invention relates to field effect transistors and more specifically GaN/AlGaN heterostructure field effect transistor with dielectric recessed gate.

### CROSS REFERENCES

The present invention is related to applications with common inventorship, titled “A Process for Fabricating Ultra-low Contact Resistances in GaN-based Devices” and “Ohmic Metal Contact and Channel Protection in GaN Devices Using an Encapsulation Layer”, filed on the same day as this application.

### BACKGROUND

Technological innovation and miniaturization continue to require robust, low noise amplifiers and high power, low weight microwave sources and MMIC's. In some situations the technology required for functional embodiments of evolving technology requires GaN/AlGaN Heterostructure Field Effect Transistors (HFETs). Attempts to fabricate GaN based heterojunction field effect transistors (HFETs) with a recessed gate structure have generally failed to satisfactorily produce high performance devices. One of the most significant problems confronting artisans is the lack of a satisfactory gate recess etch process. Existing etch processes generally result in damage to the Gallium Nitride (GaN) components. The chemical stability of GaN makes it highly desirable for its ability to ensure device reliability. The drawback to GaN is its material properties in the areas of device fabrication and processing. The drawbacks are most apparent in situations requiring the selective removal of GaN in the active regions of fabricated devices. The current state of the art provides few if any wet etchants that are suitable for both processing GaN, and are compatible with either e-beam or photolithographic masks and resolution. The existing understanding of the benefits of gate recess etching is generally recognized for GaAs and InP-based HFETs. However, gate recess etching in GaN devices without damage has not been satisfactorily achieved. Etching of the recessed gate region, utilizing Reactive Ion Etching (RIE) and other techniques has invariably resulted in significant etch-induced damage in the active region, which, in turn, degrades device performance. Therefore, there is a need for a means to obviate issues related to the selective removal of GaN in the fabrication of HFETs to form the recessed gate structure and to obtain the benefits of such a structure.

### SUMMARY OF THE INVENTION

The present invention provides a method and apparatus that effectively circumvents the need to selectively remove Gallium Nitride (GaN) in the fabrication of GaN/AlGaN Heterostructure Field Effect Transistors (HFETs), thus effectively obviating issues related to the selective removal of GaN in the fabrication of HFETs. Previously, in order to form a recessed gate, etching was required. One embodiment of the present invention provides for the benefits of the recessed gate structure without the traditional processing difficulties. The invention provides for a GaN/AlGaN heterostructure field effect transistor, having a recessed gate, which comprises a semi-insulating substrate; a buffer layer in continual contact with the semi-insulating substrate; a GaN active channel in continual contact with the buffer layer; an AlGaN barrier in continual contact with the GaN active channel; a source contact and a drain contact both in physical contact with the GaN active channel; a gate upon the AlGaN barrier; and at least one dielectric stressor upon the AlGaN barrier. The transistor of the invention uses the strong piezoelectric effect found in group III-nitride materials as the means to control electron concentration in the GaN active channel. Especially, the layer dielectric film atop the AlGaN induces biaxial stress to modulate electron concentration locally in the GaN active channel. In the present invention, while the electron concentration beneath the gate is unchanged, the electron concentration outside of the gate is increased, resulting in lateral variation of its density similar to what is found in wet-etching induced conventional recessed gate FETs.

In an alternative embodiment of the present invention, a process for making a GaN/AlGaN heterostructure field effect transistor with a dielectric recessed gate is provided. The process comprises the steps of forming an ohmic contact; implanting ions; depositing a dielectric film; annealing the film to achieve the desired stress; patterning the dielectric film; forming a gate; and providing a metal overlay and an airbridge. The Si₃N₄ layer may be tailored to provide an application-specific electron density profile for certain applications.

### BRIEF DESCRIPTION OF THE DRAWINGS

The objects, features, and advantages of the present invention will be apparent from the following detailed description of the preferred embodiment of the invention with references to the following drawings:

FIG. 1 shows a schematic diagram of a power Heterostructure Field Effect Transistor;

FIG. 2 shows a schematic electron density profile between source and drain in a recessed gate Heterostructure Field Effect Transistor; and

FIG. 3 shows a schematic diagram of a dielectric recesses GaN/AlGaN power Heterostructure Field Effect Transistor.

### DETAILED DESCRIPTION

The present invention provides a method and apparatus that effectively circumvents the need to selectively remove Gallium Nitride (GaN) in the fabrication of GaN/AlGaN Heterostructure Field Effect Transistors, thus effectively obviating issues related to the selective removal of GaN in the fabrication of HFETs. The following description, in conjunction with the referenced drawings, is presented to enable one of ordinary skill in the art to make and use the invention and to incorporate it in the context of particular applications. Various modifications, as well as a variety of uses in different applications, will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein. Furthermore it should be noted that unless explicitly stated otherwise, the figures included herein are illustrated diagrammatically and without any specific scale, as they are provided as qualitative illustrations of the concept of the present invention.

One embodiment of the present invention provides a novel GaN/AlGaN Heterostructure Field Effect Transistor structure incorporating a dielectric layer to form a recessed gate. This embodiment of the invention provides a system that simultaneously lowers access resistance and yields higher device performance while maintaining a high breakdown voltage. In one embodiment these improvements result from taking optimal advantage of the piezoelectric effect of AlGaN and GaN to simultaneously achieve lower access resistance and higher device performance while maintaining a favorable breakdown voltage. In addition to the conventional role as a passivation layer, the dielectric layer in this embodiment is an integral part of the active device structure.

The present invention finds application in all operations that utilize or need robust, low-noise amplifiers and high-power and low-weight microwave sources and MMIC's in the X-band to Ka-Band. Microwave sources weighing only a few grams and fabricated from GaN/AlGaN/SiC HEMT's can potentially deliver hundreds of Watts of microwave power at 10 GHz and are suitable components for phase-array radar and airborne radar applications. The present invention further finds application in the area of power amplifiers for wireless satellite-communication, and other wireless applications.

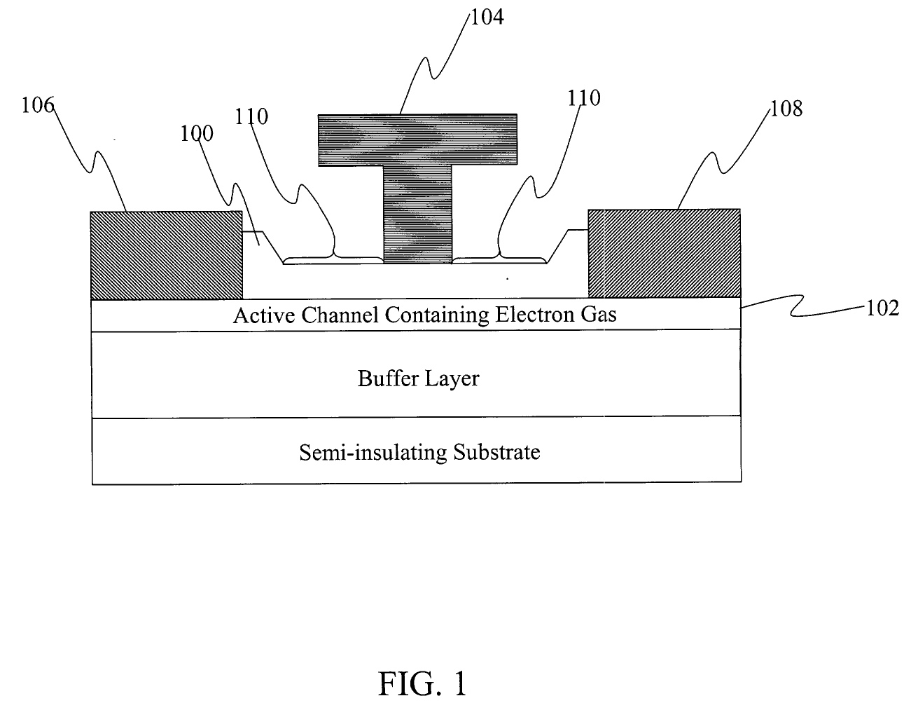

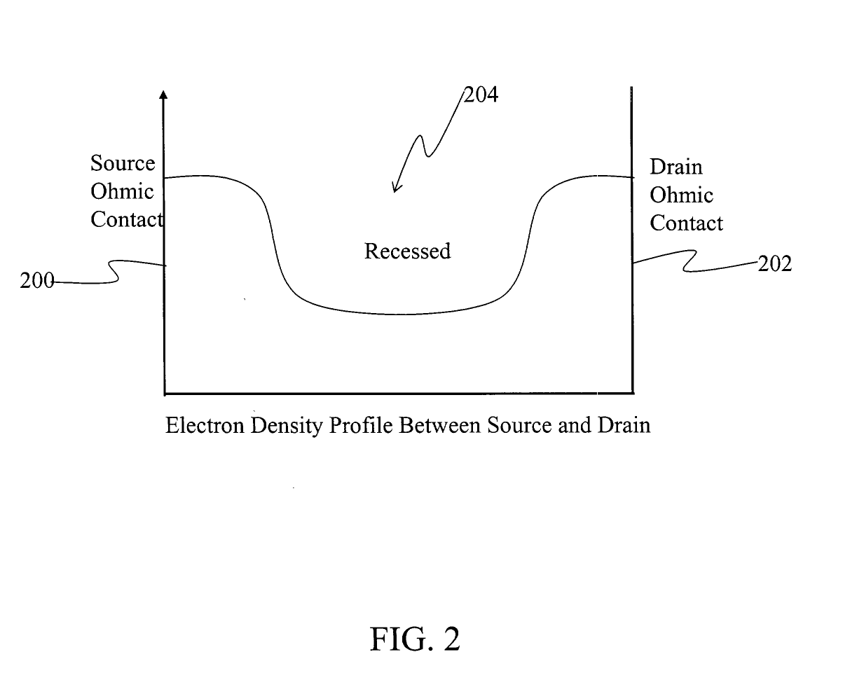

A schematic cross sectional diagram of an existing, power HFET configured for operation at microwave frequencies is set forth in FIG. 1. The region around the gate 110 is recessed to reduce the electron concentration in the active channel 102 relative to the non-recessed regions 100. The active channel 102 contains the electron gas, which has its electron profile controlled by the device. In the recessed structure, the electron concentration in the channel 102 is no longer constant. Underneath the gate 104, the electron concentration is reduced relative to the regions between the gate 104 and the source contact 106 and the drain contact 108. The resulting electron density profile is schematically depicted in FIG. 2 which illustrates the electron density profile as it exists between the source ohmic contact 200 and the drain contact 202. In the recessed region 204, the electron density is reduced.

This electron density profile provides two key benefits for power Field Effect Transistors. The first benefit is a higher breakdown voltage, and the second benefit is lower parasitic source and drain resistances. For GaAs and InP HFETs, such a density profile is obtained by partially removing the wider bandgap barrier 110 in the gate region. This partial removal is usually accomplished with a gate recess etch, as is illustrated in FIG. 1. As discussed earlier, gate recess etch techniques have not yet been satisfactorily developed for GaN systems. One embodiment of the present invention discloses a technique to achieve the desirable lateral variation of electron concentration in the channel of a GaN/AlGaN HFET without having to etch the barrier material, thereby circumventing the problems associated with GaN etching.

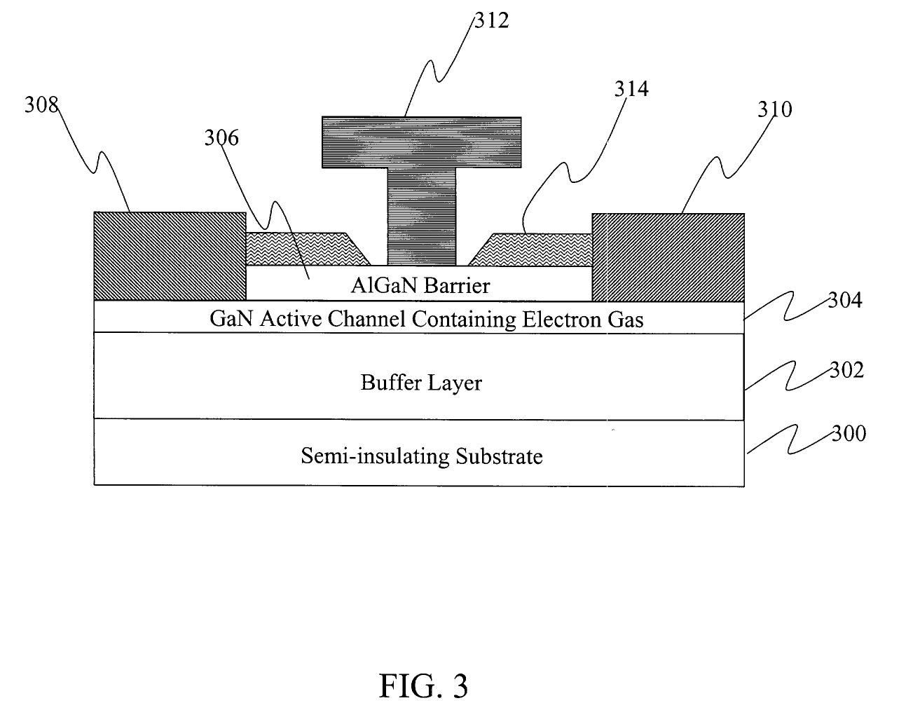

Referring now to FIG. 3 which depicts a GaN/AlGaN HFET according to the present invention, where the transistor is comprised of a semi-insulating substrate 300, a buffer layer 302 which is in continual contact with the semi-insulating substrate 300. A GaN active channel 304 is atop the buffer layer 302. An AlGaN barrier 306 is laid atop, and is in continual contact with, the GaN active channel 304. Thereafter, there is a source contact 308 and a drain contact 310 both in physical contact with the GaN active channel 304. There is a gate 312 upon the AlGaN barrier 306 and between the source contact 308 and a drain contact 310, and at least one dielectric stressor 314 upon the AlGaN barrier 306. The at least one dielectric stressor 314 is between the gate 312 and the source contact 308 and a drain contact 310.

Achieving the desirable lateral variation of electron concentration in the channel of a GaN/AlGaN HFET without having to etch the barrier material is accomplished by taking advantage of the strong piezoelectric effect found in group-III nitride materials. The invention provides that for the same heterostructure, the electron concentration at the GaN/AlGaN interface can be tuned by applying a biaxial stress to the wider bandgap AlGaN barrier. Due to the lattice mismatch between AlGaN and GaN, the GaN/AlGaN heterostructure is inherently strained, provided that the thickness of the AlGaN layer is below the critical thickness, above which relaxation occurs. The resultant piezoelectric charge is a major contributor to the electron concentration in the channel of GaN/AlGaN HFET. By selectively forming dielectric stressors 314 in the areas between the gate 312 and source contact 308 and drain contact 310 of the device, it is possible to increase the electron concentrations in these areas to create the desired density profile, schematically set forth in FIG. 2. The schematic diagram of FIG. 3 depicts a dielectric recessed GaN/AlGaN power Heterostructure Field Effect Transistor. In contrast to the GaAs and InP HFETs of FIG. 1, the dielectric recessed GaN/AlGaN HEFT does not require etching of the AlGaN barrier 306, which is a major hurdle for GaN and AlGaN processing. Rather, the HEFT of the present invention relies on the well-known and well-characterized deposition and patterning of dielectric materials such as silicon dioxide and silicon nitride.

One implementation of the dielectric recessed GaN/AlGaN HFET includes the following steps: forming an ohmic contact, implanting ions, depositing dielectric film (e.g. Si₃N₄), annealing the film to achieve the desired stress, patterning the dielectric film, forming a gate, adding a metal overlay and airbridge. In the present invention the Si₃N₄ layer plays an active role in the transport properties of the device, and it can be tailored to provide for an optimal lateral electron density profile for high-speed and high-power applications. Further, it is worth noting that the desired stressing may be achieved in using many well-known techniques, other than annealing.

In order to demonstrate the key concept of the dielectric recessed GaN HEFT, changing the electron concentration using a dielectric stressor, the electron concentration with and without the dielectric films has been measured and the results are tabulated in TABLE 1.

TABLE 1

| | | | With annealed |
|---|---|---|---|
| Wafer | As grown (cm⁻²) | With Si₃N₄ (cm⁻²) | Si₃N₄ (cm⁻²) |
| N | 1.23 * 10¹³ | 1.45 * 10¹³ (300 nm SiNx) | 1.62 * 10¹³ |
| N + 1 | 1.22 * 10¹³ | 1.45 * 10¹³ (300 nm SiNx) | 1.60 * 10¹³ |
| N + 2 | 1.22 * 10¹³ | 1.35 * 10¹³ (100 nm SiNx) | 1.47 * 10¹³ |

The data shows the present invention achieving a substantial increase in electron concentration ˜4×10¹² cm⁻² which is about the same amount as the total electron concentration in a power GaAs Power HEMT. Based on the data set forth in TABLE 1, it will be evident to one skilled in the art that the dielectric recessed GaN/AlGaN HFET provides a substantial improvement in both performance and robustness over existing GaN devices thus allowing for application in a wide variety of devices and providing superior performance characteristics.

What is claimed is:

1. A GaN/AlGaN heterostructure field effect transistor (HFET), which comprises
a semi insulating substrate;
a buffer layer in continual contact with the semi-insulating substrate;
a GaN active channel in continual contact with the buffer layer;
an AlGaN barrier in continual contact with the GaN active channel;
a source contact and a drain contact both in physical contact with the GaN active channel;
a gate upon the AlGaN barrier; and
at least one dielectric stressor upon the AlGaN barrier.

2. A GaN/AlGaN heterostructure field effect transistor as set forth in claim 1, wherein an electron concentration in the active channel is lower than an electron concentration in regions between the source contact and the drain contact.

3. A GaN/AlGaN heterostructure field effect transistor as set forth in claim 1, wherein there is a lateral variation of electron concentration in the channel of a GaN/AlGaN HFET without AlGaN barrier etching.

4. A GaN/AlGaN heterostructure field effect transistor as set forth in claim 1, which uses the strong piezoelectric effect in group III-nitride materials.

5. A GaN/AlGaN heterostructure field effect transistor as set forth in claim 4, wherein the group III-nitride material is Si₃N₄.

6. A GaN/AlGaN heterostructure field effect transistor as set forth in claim 1, wherein the electron concentration at the GaN/AlGaN interface is tuned by applying a biaxial stress to a wider bandgap AlGaN barrier.

7. A GaN/AlGaN heterostructure field effect transistor as set forth in claim 1, wherein due to the lattice mismatch between AlGaN and GaN, the GaN/AlGaN heterostructure is inherently strained and the resultant piezoelectric charge contributes to the electron concentration in the GaN active channel.

8. A GaN/AlGaN heterostructure field effect transistor as set forth in claim 1, wherein dielectric stressors are formed selectively in the areas between the gate and the source/drain contacts of the transistor, and thus an electron concentration in these areas increased, resulting in a varying electron density profile.

9. A process for making a GaN/AlGaN heterostructure field effect transistor with a dielectric recessed gate, comprising the steps of:
forming an ohmic contact;
implanting ions;
depositing a dielectric film;
annealing the film to achieve the desired stress;
patterning the dielectric film;
forming a gate; and
providing a metal overlay and an airbridge.

10. A process for making a GaN/AlGaN heterostructure field effect transistor as set forth in claim 9, wherein the dielectric film is Si₃N₄.

11. A process for making a GaN/AlGaN heterostructure field effect transistor as set forth in claim 9, wherein the Si₃N₄ layer plays an active role in the transport properties of the device.

12. A process for making a GaN/AlGaN heterostructure field effect transistor as set forth in claim 9, wherein the Si₃N₄ layer is tailored to provide an optimal electron density profile for high-speed applications.

13. A process for making a GaN/AlGaN heterostructure field effect transistor as set forth in claim 9, wherein the Si₃N₄ layer is tailored to provide an optimal electron density profile for high-power applications.

14. A transistor including a gate, source, a drain, a GaN active channel, and an AlGaN barrier, wherein the transistor utilizes a strong piezoelectric effect found in group III-nitride materials as the means to control electron concentration in a GaN active channel; and wherein a layer of dielectric film atop an AlGaN barrier induces biaxial stress to modulate electron concentration locally in the GaN active channel.

15. The transistor of claim 14 wherein, while the electron concentration beneath the gate is unchanged, the electron concentration outside the gate is increased, resulting in lateral variation in electron density, similar to the variation found in wet-etching induced, conventional recessed gate FETs.
